(19) United States
(12) Patent Application Publication
(10) Pub. No.: US 2024/0178346 A1
(43) Pub. Date: May 30, 2024

(54) MICRO LIGHT-EMITTING DIODE AND DISPLAY PANEL

(71) Applicant: Tianjin Sanan Optoelectronics Co., Ltd., Tianjin (CN)

(72) Inventors: Jinghua CHEN, Tianjin (CN); Chincheng HSU, Tianjin (CN); Yenchin WANG, Tianjin (CN); Shaohua HUANG, Xiamen (CN); Yuren PENG, Tianjin (CN); Huanshao KUO, Tianjin (CN)

(21) Appl. No.: 18/433,466

(22) Filed: Feb. 6, 2024

Related U.S. Application Data
(63) Continuation of application No. PCT/CN2021/113670, filed on Aug. 20, 2021.

(51) Int. Cl. H01L 33/30; H01L 25/075; H01L 33/10; H01L 33/22

(52) U.S. Cl. CPC H01L 33/305; H01L 25/0753; H01L 33/10; H01L 33/22

(57) ABSTRACT

A micro light-emitting diode and a display panel are provided. The micro light-emitting diode includes a semiconductor epitaxial stacked layer including a first semiconductor layer, a second semiconductor layer and an active layer therebetween; a first electrode electrically connected to the first semiconductor layer, and a second electrode electrically connected to the second semiconductor layer. The second semiconductor layer includes an N-type gallium phosphide (GaP) window layer, and the N-type GaP window layer plays a role in current spreading. The problem of low luminous efficiency of the micro light-emitting diode at a low current density can be solved and the luminous efficiency of the micro light-emitting diode at a low current density can be improved.

### TECHNICAL FIELD

The disclosure relates to the field of semiconductor manufacturing, and more particularly to a micro light-emitting diode and a display panel.

### BACKGROUND

Micro light-emitting diode (mLED) has advantages of self-luminescence, high efficiency, low power consumption, high brightness, high stability, ultra-high resolution and color saturation, fast response speed, and long service life. It has been applied in the fields of display, optical communication, indoor positioning, biology and medical treatment, and is expected to be further extended to wearable/implantable devices, enhanced display/virtual reality, vehicle display, super-large display, optical communication/optical interconnection, medical detection, intelligent car lights, space imaging and other fields, with clear and considerable market prospects.

The size of the mLED is less than 100 micrometers (μm), and there are defects on a sidewall of the mLED, which will lead to non-radiative recombination, thus affecting the luminous efficiency of the mLED. As the size of the mLED becomes smaller and smaller, the phenomenon of non-radiative recombination caused by the defect of the sidewall of the mesa will become more and more serious.

Due to the non-radiative recombination caused by sidewall effect, the existing mLEDs have low luminous efficiency under the condition of low current density. Therefore, it is urgent to develop a mLED to improve the luminous efficiency under the condition of low current density.

### SUMMARY

In order to solve the above problems, the disclosure provides a micro light-emitting diode. The micro light-emitting diode includes a semiconductor epitaxial stacked layer, a first electrode, and a second electrode. The semiconductor epitaxial stacked layer includes a first semiconductor layer, a second semiconductor layer, and an active layer located between the first semiconductor layer and the second semiconductor layer. The first electrode is electrically connected to the first semiconductor layer. The second electrode is electrically connected to the second semiconductor layer. The second semiconductor layer includes an N-type gallium phosphide (GaP) window layer, and the N-type GaP window layer is configured (i.e., structured and arranged) to play a role in current spreading.

In addition, the disclosure also provides a micro light-emitting diode, which includes a semiconductor epitaxial stacked layer, a first electrode, and a second electrode. The semiconductor epitaxial stacked layer includes a first semiconductor layer, a second semiconductor layer, and an active layer located between the first semiconductor layer and the second semiconductor layer. The first electrode is electrically connected to the first semiconductor layer. The second electrode is electrically connected to the second semiconductor layer. The second semiconductor layer includes an N-type GaP window layer, and a thickness of the N-type GaP window layer is in a range of 100-2000 nanometers (nm).

Moreover, the disclosure also provides a preparation method of a micro light-emitting diode, which includes steps as follows:
step (1), manufacturing a semiconductor epitaxial stacked layer on a growth substrate, where the semiconductor epitaxial stacked layer includes a first semiconductor layer, a second semiconductor layer, and an active layer located between the first semiconductor layer and the second semiconductor layer; and
step (2), fabricating a first electrode and a second electrode on the first semiconductor layer and the second semiconductor layer respectively, and electrically connecting the first electrode and the second electrode to the first semiconductor layer and the second semiconductor layer respectively;
the second semiconductor layer including an N-type GaP window layer.

The disclosure also provides a display panel, which includes the micro light-emitting diode.

The disclosure has beneficial effects as follows.

In a first aspect, as a window layer, the N-type GaP has a high electron mobility. At low current density, more electrons flow down to the active layer to recombine with holes, and less to the sidewall, which can reduce the non-radiative recombination of the sidewall and improve the luminous efficiency.

In a second aspect, as a window layer, the N-type GaP has better light transmittance than aluminum gallium indium phosphide (AlGaInP), which can increase the transmission of light emitted by the active layer, and then radiate from the light-emitting surface through the reflection of the metal electrode, thus improving the luminous efficiency.

In a third aspect, as an ohmic contact layer, the N-type GaP replaces the N-type gallium arsenide (GaAs) or AlGaInP, which can reduce light absorption and improve luminous efficiency.

### BRIEF DESCRIPTION OF DRAWINGS

FIG. 1 illustrates a schematic sectional view of a micro light-emitting diode in the related art.

FIG. 2 illustrates a schematic cross-sectional view of a micro light-emitting diode according to an embodiment 1 of the disclosure.

FIG. 3 illustrates a schematic cross-sectional view of a micro light-emitting element according to the embodiment 1 of the disclosure.

FIGS. 4 to 11 illustrate schematic diagrams showing a process of manufacturing a micro light-emitting diode according to an embodiment 2 of the disclosure.

FIG. 12 illustrates a comparison between test data of external quantum efficiency (EQE)-current density of the micro light-emitting diode in the embodiment 2 of the disclosure and a traditional structure.

FIG. 13 illustrates a schematic cross-sectional view of a micro-luminescent element according to an embodiment 3 of the disclosure.

FIG. 14 illustrates a schematic cross-sectional view of a micro light-emitting diode according to an embodiment 4 of the disclosure.

FIG. 15 illustrates a schematic cross-sectional view of a micro light-emitting diode according to an embodiment 5 of the disclosure.

FIG. 16 illustrates a schematic diagram of a display panel according to an embodiment 6 of the disclosure.

### DETAILED DESCRIPTION OF EMBODIMENTS

### Embodiment 1

FIG. 1 illustrates a schematic diagram of a micro light-emitting diode in the related art. In the micro light-emitting diode, a first semiconductor layer is N-doped, including an N-type cladding layer 121 and an N-type aluminum gallium indium phosphide (AlGaInP) window layer 120. A second semiconductor layer is P-doped, including a P-type cladding layer 123 and a P-type gallium phosphide (GaP) window layer 124. An active layer 122 is a multiple quantum well (MQW) structure, which is made of materials of Alₙ₁Ga₁₋ₙ₁InP/Alₙ₂Ga₁₋ₙ₂InP (0≤n1≤n2≤1) repeatedly stacked wells and barriers. A first electrode 105 is electrically connected to the first semiconductor layer, and the second electrode 106 is electrically connected to the second semiconductor layer. In the micro light-emitting diode in the related art, the P-type GaP window layer 124 is used as a current spreading layer. Because the hole mobility of the P-type GaP is slow, the sidewall effect is serious when carriers flow to the sidewall at low current, thus the luminous efficiency of the micro light-emitting diode is extremely low at low current density.

In this embodiment, a micro light-emitting diode and a manufacturing method thereof are provided, which can solve the technical problem of low luminous efficiency of the micro light-emitting diode at low current density in the related art. The micro light-emitting diode refers to a micron-size light-emitting diode, and its manufacturing process is greatly different from that of the traditional light-emitting diode due to the small size of the micro light-emitting diode. The micro light-emitting diode in the disclosure mainly refers to the size of the light-emitting diode, including the length, width or height ranging from greater than or equal to 2 micrometers (μm) to less than 5 μm, from greater than or equal to 5 μm to less than 10 μm, from greater than or equal to 10 μm to less than 20 μm, from greater than or equal to 50 μm to less than 100 μm. The micro light-emitting diode can be widely used in display and other fields.

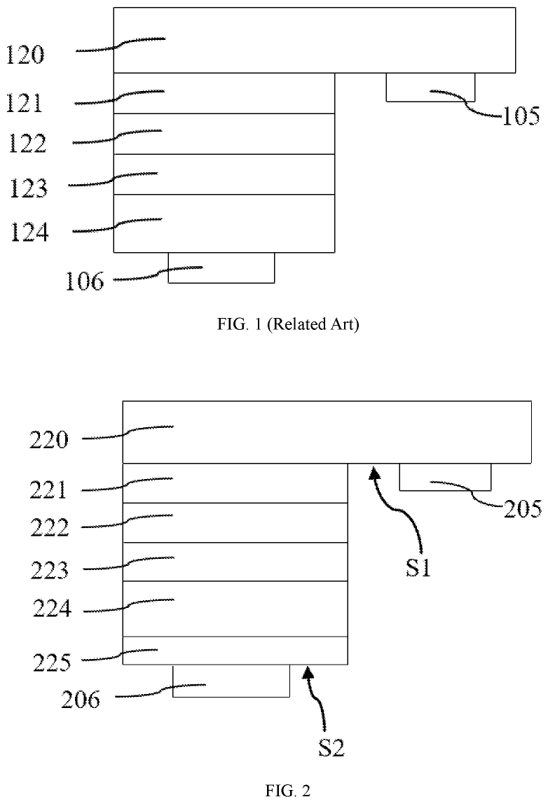

As shown in FIG. 2, the micro light-emitting diode includes a semiconductor epitaxial stacked layer, a first mesa S1, a second mesa S2, a first electrode 205, and a second electrode 206. The semiconductor epitaxial stacked layer includes a first semiconductor layer, a second semiconductor layer, and an active layer 222 located between the first semiconductor layer and the second semiconductor layer. The first mesa S1 is composed of the first semiconductor layer exposed by the semiconductor epitaxial stacked layer, and the second mesa S2 is composed of the second semiconductor layer. The first electrode 205 is formed on the first mesa S1 and electrically connected to the first semiconductor layer. The second electrode 206 is formed on the second mesa S2 and electrically connected to the second semiconductor layer.

The first semiconductor layer and the second semiconductor layer respectively include a first cladding layer 221 and a second cladding layer 223 that provide electrons and holes for the active layer 222 respectively, the materials of the first cladding layer 221 and the second cladding layer 223 are, for example, AlGaInP, aluminum indium phosphide (AlInP), or aluminum gallium arsenide (AlGaAs). In a specific embodiment, when the active layer 222 is made of AlGaInP, the first cladding layer 221 and the second cladding layer 223 made of AlInP respectively provide holes and electrons. In order to improve the uniformity of current spreading, the first semiconductor layer further includes a first window layer 220, and the second semiconductor layer further includes a second window layer 224.

The active layer 222 is a region where electrons and holes are recombined to provide light radiation, and different materials can be selected according to different emission wavelengths. The active layer 222 can be a single quantum well or a periodic structure of a multiple quantum well. The active layer 222 includes a well layer and a barrier layer, in which the barrier layer has a larger band gap than the well layer. By adjusting the composition ratio of the semiconductor material in the active layer 222, it is expected to radiate light with different wavelengths. In this embodiment, the active layer 222 radiates light in a wavelength band of 550-950 nanometers (nm), such as red, yellow, orange and infrared light. The active layer 222 is a material layer that provides electroluminescent radiation, such as AlGaInP or AlGaAs. In a specific embodiment, the active layer 222 is made of AlGaInP, and AlGaInP is a single quantum well or a multiple quantum well.

The semiconductor epitaxial stacked layer can be formed on a growth substrate by physical vapor deposition (PVD), chemical vapor deposition (CVD), epitaxy growth technology, and atomic layer deposition (ALD).

As an implementation, as shown in Table 1, main parts of the semiconductor epitaxial stacked layer of the micro light-emitting diode are provided. The first semiconductor layer is P-doped, including a P-type cladding layer 221 and a P-type window layer 220. The second semiconductor layer is N-doped, including an N-type cladding layer 223, an N-type window layer 224, and an N-type ohmic contact layer 225. An active layer 222 is a MQW structure, which is made of materials of Alₙ₁Ga₁₋ₙ₁InP/Alₙ₂Ga₁₋ₙ₂InP (0≤n1≤n2≤1) repeatedly stacked wells and barriers.

TABLE 1

| Reference | | | Thickness | |
|---|---|---|---|---|
| sign | Functional layer | Material | (nm) | Function |
| 225 | N-type ohmic | GaP + Si | 5-100 | Ohmic contact |
| | contact layer | | | |
| 224 | N-type window | GaP + Si | 50-5000 | Current spreading |
| | layer | | | |
| 223 | N-type cladding | AlInP + Si | 50-5000 | Providing electrons |
| | layer | | | |
| 222 | Luminescent layer, | Alₙ₁Ga₁₋ₙ₁InP/ | 2-50 pairs | Luminescent layer is the main |
| | MQW (i.e., active | Alₙ₂Ga₁₋ₙ₂InP | | factor to determine the |
| | layer) | (0 ≤ n1 ≤ n2 ≤ 1) | | wavelength and brightness of |
| | | | | luminescence. |
| 221 | P-type cladding | AlInP + Mg | 50-5000 | Providing holes |
| | layer | | | |
| 220 | P-type window | Alₓ₁Ga₁₋ₓ₁InP | 2500-5000 | Ohmic contact, current |
| | layer | | | spreading and light-emitting |
| | | | | layer |

In this embodiment, the first semiconductor layer includes the P-type window layer 220 and the P-type cladding layer 221. Specifically, the P-type window layer 220 plays the role of current spreading, and its spreading ability is related to its thickness. In this embodiment, the material of the P-type window layer 220 is Alₓ₁Ga₁₋ₓ₁InP with a thickness of 2500-5000 nm, and a P-type doping concentration is 2E18-5E18/cm³. The x1 in Alₓ₁Ga₁₋ₓ₁InP is in a range of 0.3 to 0.7, which can ensure the light transmittance of the P-type window layer 220. The P-type window layer 220 is in ohmic contact with the first electrode 205 to form an electrical connection. A side of the P-type window layer 220 facing away from the active layer 222 provides a light-emitting surface. The P-type cladding layer 221 serves to provide holes for the active layer 222, and the material of the P-type cladding layer 221 is AlInP with a thickness of 20-5000 nm. Magnesium (Mg) doping is common in P-type doping, and the doping of other elements equivalent substitution is not excluded.

The second semiconductor layer includes the N-type cladding layer 223, the N-type window layer 224, and the N-type ohmic contact layer 225. Specifically, the N-type cladding layer 223 is used to provide electrons for MQW, and the material is AlInP with a thickness of 50-5000 nm. Silicon (Si) doping is common in N-type doping, and the doping of other elements equivalent substitution is not excluded. The N-type window layer 224 plays the role of current spreading, and its spreading ability is related to its thickness. Therefore, in this embodiment, the thickness of the N-type window layer 224 can be selected according to the specific device size, and the thickness is controlled to be above 50 nm and below 5000 nm. In a specific embodiment, the thickness of the N-type window layer 224 is 100-2000 nm. In this embodiment, the material of the N-type window layer 224 is GaP, and an N-type doping concentration is 1E18-5E18/cm³. Si doping is common in N-type doping, and the doping of other elements equivalent substitution is not excluded.

Due to the fast electron mobility of N-type GaP, the current flows down to MQW to recombine with holes at low current, and less flows to the sidewall, thus solving the technical problem of low luminous efficiency of the micro-light-emitting diode at low current density and improving the luminous efficiency of the micro-light-emitting diode. In this situation, as a window layer, N-type GaP has better light transmittance than AlGaInP, which can increase the transmission of light emitted by the active layer 222, and then radiate from the light-emitting surface through the reflection of the metal electrode, thus improving the luminous efficiency.

The N-type ohmic contact layer 225 is disposed on the N-type window layer 224, and the material of the N-type ohmic contact layer 225 is GaP, with a thickness of 5-100 nm and a doping concentration of 5E18-5E19/cm³. In a specific embodiment, the doping concentration of the N-type ohmic contact layer 225 is above 1E19/cm³, which can form a good ohmic contact with the second electrode 206. The N-type ohmic contact layer 225 is in ohmic contact with the second electrode 206 to form an electrical connection. The N-type ohmic contact layer 225 is made of GaP material instead of N-type GaAs or N-type AlGaInP material, which can reduce the light absorption effect and improve the luminous efficiency.

The conductive metal that the first electrode 205 is in contact with the P-type window layer 220 of the first semiconductor layer can be selected from gold, platinum, silver, etc., or a transparent conductive oxide, specifically indium tin oxide (ITO), zinc oxide (ZnO), etc. In a specific embodiment, the first electrode 20 can be a multi-layer material, such as an alloy material including at least one of gold-germanium-nickel (Au—Ge—Ni), gold-beryllium (Au—Be), Au—Ge, Au—Zn, etc. In another specific embodiment, the first electrode 205 can further include a reflective metal, such as Au or silver, which reflects part of the light radiated from the active layer 222 and penetrating through the P-type window layer 220 of the first semiconductor layer to the semiconductor epitaxial stacked layer, and emits light from the light-emitting side.

In order to form a good ohmic contact with the N-type ohmic contact layer 225 of the second semiconductor layer, the material that the second electrode 206 is in contact with the N-type ohmic contact layer 225 can be a conductive metal such as Au, platinum, or silver. In a specific embodiment, the second electrode 206 may include a multi-layer material, including an alloy material containing at least one of Au—Ge—Ni, Au—Be, Au—Ge, Au—Zn, etc. In another specific embodiment, in order to improve the ohmic contact effect between the second electrode 206 and the N-type ohmic contact layer 225, the second electrode 206 may at least include a metal that can diffuse to the N-type ohmic contact layer 225 to improve the ohmic contact resistance, and a fusion of at least 300° ° C. can be selected for facilitated diffusion. The diffusional metal is a metal that can directly contact one side of the N-type ohmic contact layer 225, such as Au, platinum or silver.

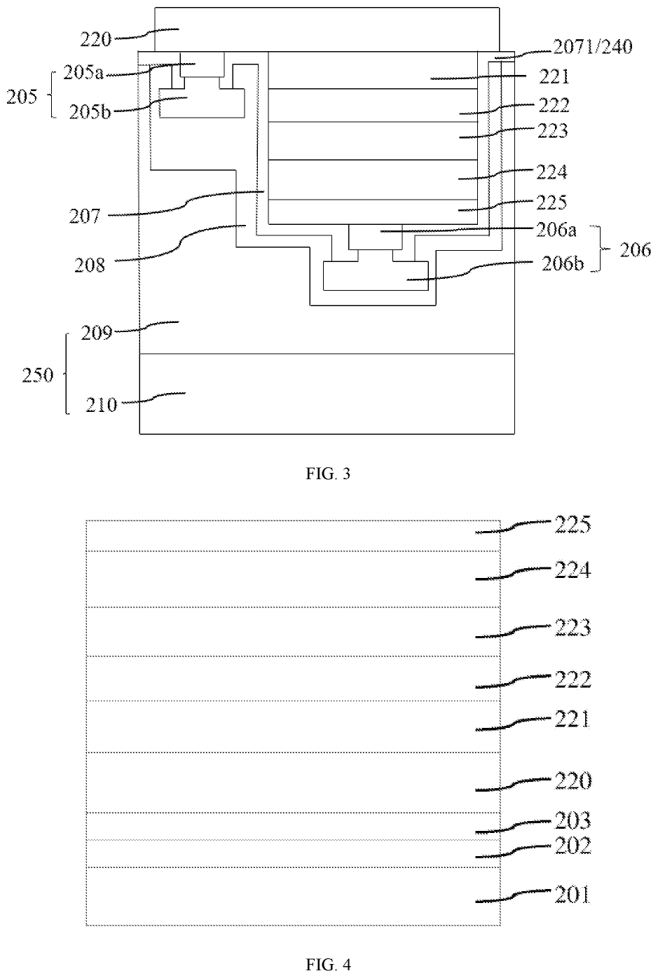

In order to improve the reliability of the micro light-emitting diode, an insulation protection layer 207 (as shown in FIG. 3) is disposed on the first mesa S1, the second mesa S2 and the sidewall of the micro light-emitting diode. The insulation protection layer 207 has a single-layer or a multi-layer structure and is made of at least one material of SiO₂, SiNₓ, Al₂O₃, and Ti₃O₅. In some alternative embodiments, the insulation protection layer 207 is a Bragg reflective layer structure, for example, the insulation protection layer 207 is formed by alternately stacks of two materials, Ti₃O₅ and SiO₂. In this embodiment, the insulation protection layer 207 can be made of SiNₓ or SiO₂ with a thickness of more than 1 μm.

In this embodiment, the first electrode 205 and the second electrode 206 are located at a side opposite to the light-emitting side, and the first electrode 205 and the second electrode 206 can contact an external electrical connector through the opposite side of the light-emitting side to form a flip-chip structure. Therefore, the first electrode 205 and the second electrode 206 both further include a top pad metal, which can be at least one layer such as Au, Al, or silver, so as to realize die bonding of the first electrode 205 and the second electrode 206. The first electrode 205 and the second electrode 206 may have the same height or different heights, and the pad metal layers of the first electrode and the second electrode do not overlap in the thickness direction.

FIG. 3 illustrates a schematic diagram of a micro light-emitting element formed by using the micro light-emitting diode of this embodiment, and the micro light-emitting element further includes a pedestal 250 used to support the micro light-emitting diode, and the pedestal 250 is located at a lower side of the micro light-emitting diode. The micro light-emitting element further includes a bridge arm 240 used to connect the micro light-emitting diode and the pedestal 250. The pedestal 250 includes a substrate 210 and a bonding layer 209, the bonding layer 209 is made of bisbenzocyclobutene (BCB) adhesive, silicone, ultraviolet (UV) adhesive, or resin, and the material of the bridge arm 240 includes dielectric, metal, or semiconductor material. In some embodiments, a horizontal portion 2071 of the insulation protection layer 207 can act as the bridge arm 240 spanning the bonding layer 209, and connecting the micro light-emitting diode and the pedestal 250.

The micro light-emitting diode is separated from the pedestal 250 by stamp transfer printing, and the stamp printing material is poly(dimethylsiloxane) (PDMS), silicone, pyrolysis adhesive, or UV-adhesive. In some cases, there is a sacrificial layer 208 located between the micro light-emitting diode and the pedestal 250. At least in certain cases, the removal efficiency of the sacrificial layer 208 is higher than that of the micro light-emitting diode, including chemical decomposition or physical decomposition, such as ultraviolet light decomposition, etching removal, or impact removal.

### Embodiment 2

FIGS. 4-11 illustrate schematic diagrams of a manufacturing process of the micro light-emitting diode according to the embodiment 1, and a manufacturing method of the micro light-emitting diode according to this embodiment will be described in detail below in combination with the schematic diagrams.

First, referring to FIG. 4, an epitaxial structure is provided, which specifically includes steps as follows. A growth substrate 201 is provided, and a semiconductor epitaxial stacked layer is epitaxially grown on the growth substrate 201 through an epitaxial process such as metal-organic chemical vapor deposition (MOCVD). The semiconductor epitaxial stacked layer includes a buffer layer 202 and an etching stop layer 203 sequentially stacked on a surface of the growth substrate 201 for removing the epitaxial growth substrate 201. Then, a first semiconductor layer including a P-type window layer 220 and a P-type cladding layer 221, an active layer 222, and a second semiconductor layer including an N-type cladding layer 223, an N-type window layer 224, and an N-type ohmic contact layer 225 are grown.

In this embodiment, the growth substrate 201 is a commonly used GaAs substrate, and the material of the buffer layer 202 is set according to the growth substrate 201. It should be noted that the material of the growth substrate 201 is not limited to GaAs, and another material, such as GaP or InP, can be used, and the corresponding setting and material of the buffer layer 202 can be selected according to the specific growth substrate 201. The etching stop layer 203, such as GaInP, is provided on the buffer layer 202. In order to facilitate the subsequent removal of the subsequent growth substrate 201, a thinner etching stop layer 203 is provided, and its thickness is controlled within 500 nm. In a specific embodiment, the thickness of the etching stop layer 203 is controlled within 200 nm.

In this embodiment, the P-type window layer 220 is made of Alₓ₁Ga₁₋ₓ₁InP with a thickness of 2500-5000 nm and a P-type doping concentration of 2E18-5E18/cm³. The x1 in Alₓ₁Ga₁₋ₓ₁InP is in a range of 0.3 to 0.7, which can ensure the light transmittance of the P-type window layer 220. The function of the P-type cladding layer 221 is to provide holes for MQW, and the material is AlInP with a thickness of 20-5000 nm. Mg doping is common in P-type doping, and the doping of other elements equivalent substitution is not excluded. The active layer 222 is a multi-quantum well, which is made of the material of Alₙ₁Ga₁₋ₙ₁InP/Alₙ₂Ga₁₋ₙ₂InP (0≤n1≤n2≤1) repeatedly stacked wells and barriers.

The material of N-type cladding layer 223 is AlInP with a thickness of 50-5000 nm. The N-type window layer 224 plays the role of current spreading, and its spreading ability is related to the thickness, the thickness of the N-type window layer 224 is above 50 nm and below 5000 nm. In a specific embodiment, the thickness of the N-type window layer 224 is in a range of 100-2000 nm. In this embodiment, the material of the N-type window layer 224 is GaP, and the N-type doping concentration is 1E18-5E18/cm³. The material of the N-type ohmic contact layer 225 is GaP, with a thickness of 5-100 nm, and the N-type doping concentration is 5E18-5E19/cm³. In a specific embodiment, the N-type doping concentration of the N-type ohmic contact layer 225 is above 1E19/cm³.

As the window layer, the N-type GaP has a high electron mobility, so the current flows directly down to MQW to recombine with holes at low current, and less flows to the sidewall, thus solving the technical problem of low luminous efficiency of micro light-emitting element at low current density and improving the luminous efficiency of micro light-emitting element. In addition, as the window layer, the N-type GaP has better light transmittance than AlGaInP, which can increase the transmission of light emitted by the active layer and then radiate from the light-emitting surface through the reflection of the metal electrode, thus improving the luminous efficiency.

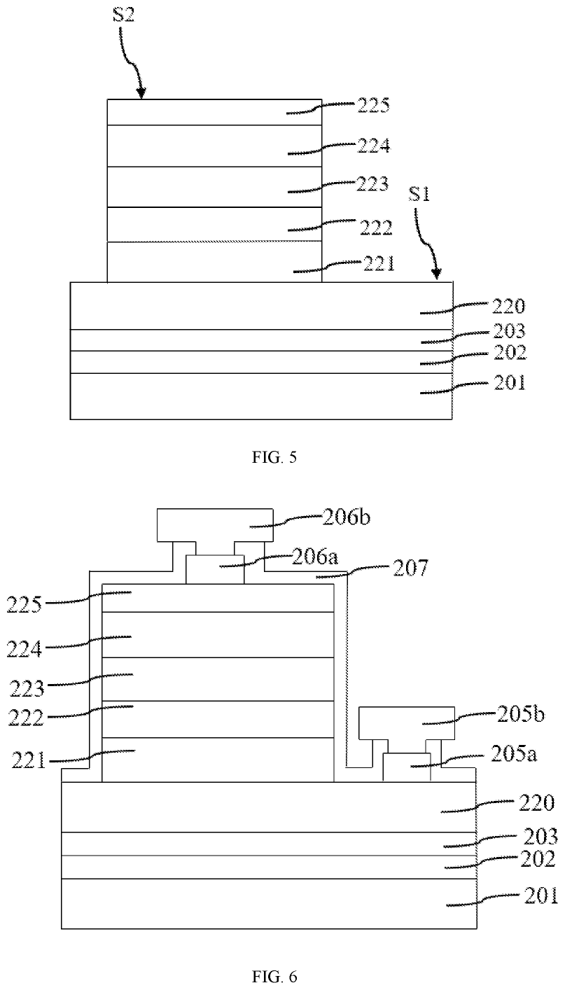

Referring to FIG. 5, a portion of the semiconductor epitaxial stacked layer is removed by dry etching to form a first mesa S1 and a second mesa S2. The first mesa S1 is composed of the first semiconductor layer exposed by the semiconductor epitaxial stacked layer, and the second mesa S2 is composed of the second semiconductor layer. A sidewall is formed at an outer edge of the semiconductor epitaxial stacked layer and between the first mesa S1 and the second mesa S2.

Referring to FIG. 6, a first electrode 205 and a second electrode 206 are respectively fabricated on the first mesa S1 and the second mesa S2. The first electrode 205 includes an ohmic contact portion 205a, and the second electrode 206 includes an ohmic contact portion 206a. An insulation protection layer 207 is disposed on the ohmic contact portions 205a and 206a, and openings are defined above the insulation protection layer 207 to form pad electrodes 205b and 206b in contact with the ohmic contact portions 205a and 206a, respectively. The material of the ohmic contact portions 205a and 206a can be, for example, Au/AuZn/Au or AuGeNi or AuZn or AuGe, and in this step, the ohmic contact portions 205a and 206a can be fused to form a good ohmic contact with the semiconductor epitaxial stacked layer. The insulation protection layer 207 is made of SiNₓ or SiO₂, and its thickness is greater than 1 μm. In other alternative embodiments, the insulation protection layer 207 can adopt a Bragg reflective layer structure, which is formed by alternately stacks of two materials with different refractive indices.

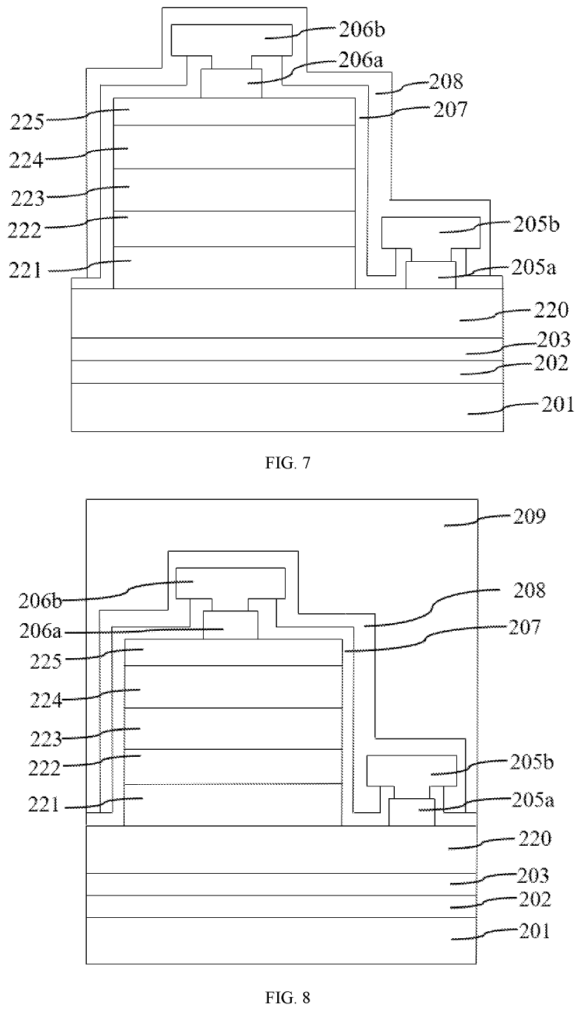

Referring to FIG. 7, a sacrificial layer 208 is disposed on the surface of the micro light-emitting diode. A thickness of the sacrificial layer 208 covering the sidewall is greater than 1 μm, and the material of the sacrificial layer 208 can be oxide, nitride or a material that can be selectively removed relative to other layers.

Referring to FIG. 8, a bonding adhesive, such as BCB adhesive, is bonded on the sacrificial layer 208 of the micro light-emitting diode to form a bonding layer 209.

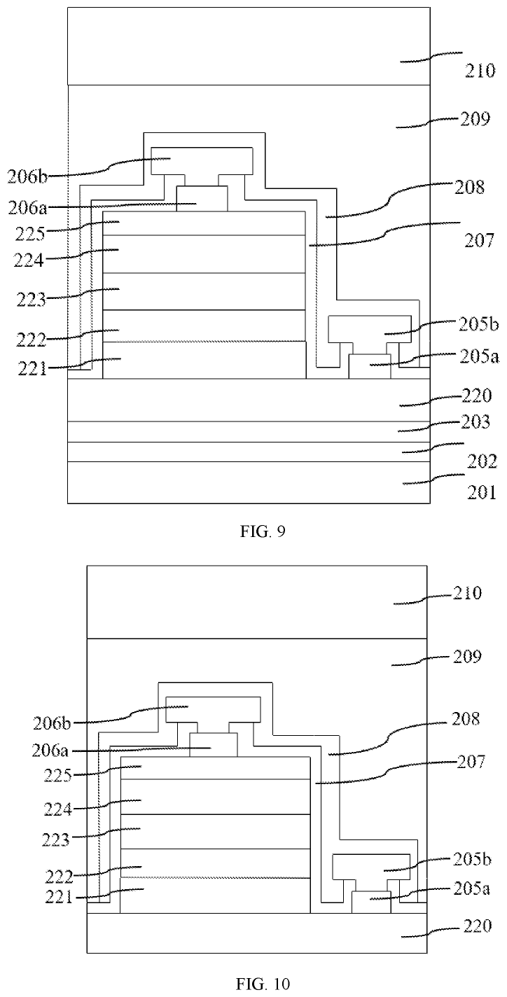

Referring to FIG. 9, a wafer on which the micro light-emitting diode is distributed is bonded to the substrate 210.

Referring to FIG. 10, the growth substrate 201 is peeled off, and the buffer layer 202 and the etching stop layer 203 are removed.

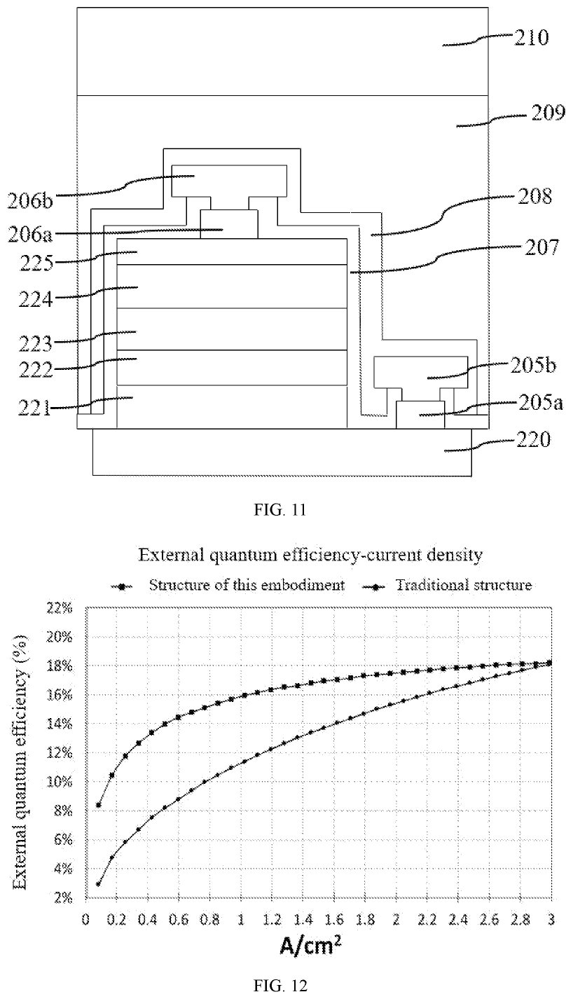

Referring to FIG. 11, the first semiconductor layer on the edge of the micro light-emitting diode is removed by masking and etching, and the etching stops on the insulation protection layer 207 to form an independent core particle, which is convenient for the subsequent separation of the core particle.

Finally, the formed micro light-emitting diode is separated from the substrate 210 by transfer printing and transferred to a package substrate (not shown in the figure).

The micro light-emitting diode chip is manufactured by the manufacturing method in this embodiment, and a horizontal dimension of the chip is 34*58 μm. After the single chip is packaged, the change of external quantum efficiency (EQE) with current density (J) is tested. As shown in FIG. 12, under the condition of low current density of 0.1 Amperes per square centimeter (A/cm²), EQE is increased by 1.89 times from 2.9% to 8.4%.

### Embodiment 3

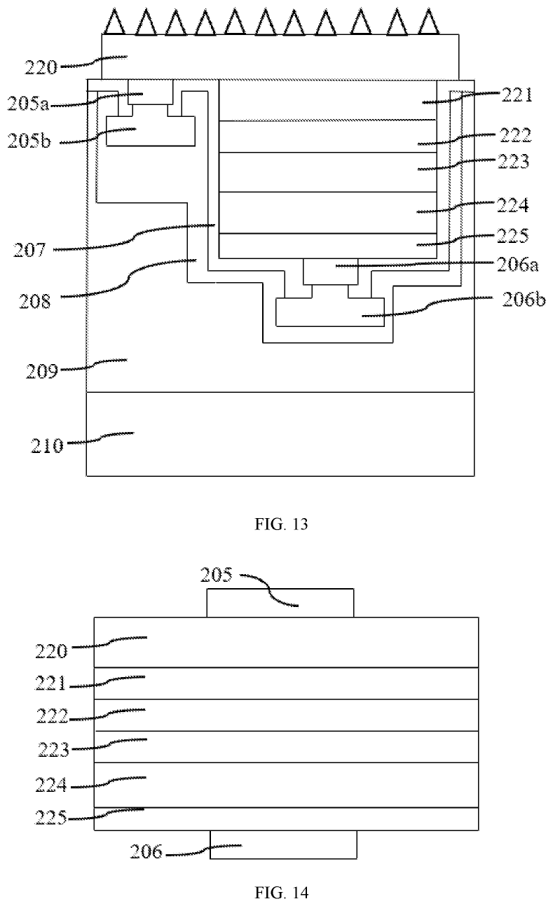

Compared with the micro light-emitting element illustrated in FIG. 3 of the embodiment 1, in order to further improve the efficiency of the light emitted from the active layer 222 from the light-emitting surface, as shown in FIG. 13, the surface of the N-type window layer 220 has a roughened structure, which is composed of regular or irregular protrusions.

### Embodiment 4

Compared with the micro light-emitting diode illustrated in FIG. 2 in the embodiment 1, as shown in FIG. 14, the first electrode 205 and the second electrode 206 are located at different sides, and the micro light-emitting diode in this embodiment has a vertical structure. The side of the P-type window layer 220 facing away from the active layer 222 is a light-emitting surface, and a reflective metal or reflective insulation dielectric layer (not shown in the figure) can be disposed between the N-type ohmic contact layer 225 and the second electrode 206, so that part of the light radiated from the active layer and penetrating through the window layer 220 of the first semiconductor layer will be reflected to the semiconductor epitaxial stacked layer, and light will be emitted from the light-emitting side.

### Embodiment 5

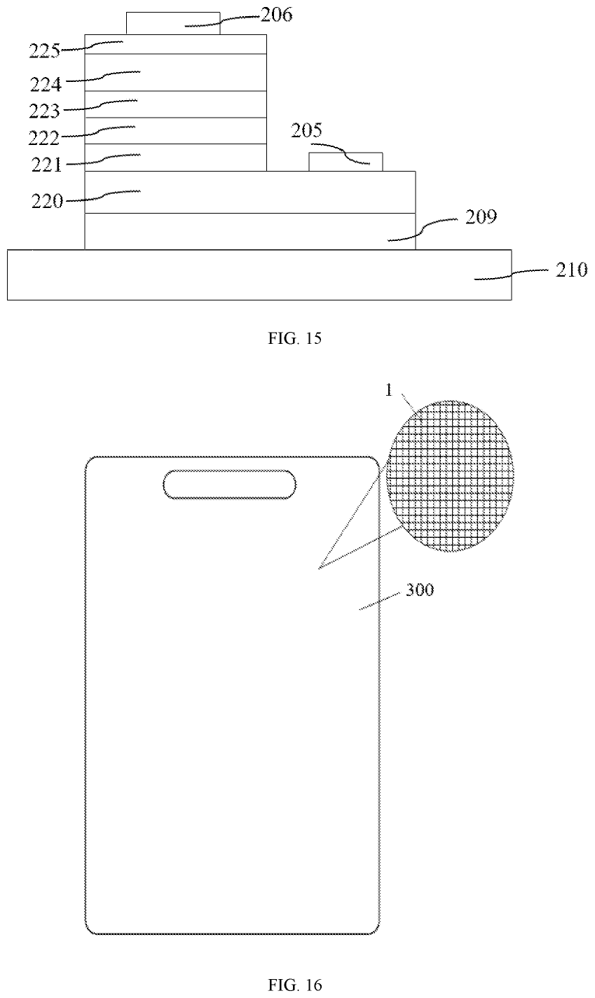

Compared with the micro-light-emitting element illustrated in FIG. 3 in the embodiment 1, as shown in FIG. 15, the micro-light-emitting diode is bonded on the substrate 210 by the bonding layer 209 (also referred to as bonding adhesive), which can be BCB adhesive or polyimide (PI), and the substrate 210 can be a sapphire substrate. The micro light-emitting element in this embodiment can be transferred to a package substrate by laser peeling (not shown in the figure).

### Embodiment 6

This embodiment provides a display panel 300, with reference to FIG. 16, the display panel 300 includes multiple micro light-emitting diodes arranged in an array as in any of the foregoing embodiments, and FIG. 16 schematically shows a portion of the micro light-emitting diodes 1 in an enlarged manner.

In this embodiment, the display panel 300 is a display panel corresponding to a display screen of a smart phone. In other embodiments, the display panel can also be the display panel of other electronic products, such as a display panel of a computer display screen or a display panel of a display screen of a smart wearable electronic product.

With the micro light-emitting diodes (micro light-emitting diodes 1) of the foregoing embodiments, the display panel 300 has the advantages brought by the micro light-emitting diodes of the foregoing embodiments.

According to the micro light-emitting diode and the manufacturing method thereof provided by the disclosure, the N-type GaP as the window layer in the micro light-emitting diode has fast electron mobility. When the current density is low, more electrons flow downwards to the active layer to recombine with holes, and less flows to the sidewall, so that the non-radiative recombination of the sidewall can be reduced and the luminous efficiency can be improved. The N-type GaP as a window layer has better light transmittance than AlGaInP, which can increase the light transmission from the active layer and then radiate from the light-emitting surface through the reflection of the metal electrode, thus improving the luminous efficiency. The N-type GaP as the ohmic contact layer replaces N-type GaAs layer, which can reduce light absorption and improve luminous efficiency.

What is claimed is:

1. A micro light-emitting diode, comprising:
a semiconductor epitaxial stacked layer, comprising a first semiconductor layer, a second semiconductor layer, and an active layer located between the first semiconductor layer and the second semiconductor layer;
a first electrode, electrically connected to the first semiconductor layer; and
a second electrode, electrically connected to the second semiconductor layer;
wherein the second semiconductor layer comprises an N-type gallium phosphide (GaP) window layer, and the N-type GaP window layer is configured to play a role in current spreading.

2. The micro light-emitting diode as claimed in claim 1, wherein a thickness of the N-type GaP window layer is in a range of 50-5000 nanometers (nm).

3. The micro light-emitting diode as claimed in claim 1, wherein a light-emitting surface is provided on a side of the first semiconductor layer facing away from the active layer, and the N-type GaP window layer of the second semiconductor layer is located on a side of the active layer facing away from the light-emitting surface.

4. The micro light-emitting diode as claimed in claim 1, wherein a doping concentration of the N-type GaP window layer is in a range of 1E18-5E18 per cubic centimeters (/cm³).

5. The micro light-emitting diode as claimed in claim 1, wherein the second semiconductor layer further comprises a GaP ohmic contact layer, a light-emitting surface is provided on a side of the first semiconductor layer facing away from the active layer, and the GaP ohmic contact layer is located on a side of the active layer facing away from the light-emitting surface and located between the active layer and the second electrode.

6. The micro light-emitting diode as claimed in claim 5, wherein a thickness of the GaP ohmic contact layer is in a range of 5-100 nm, the GaP ohmic contact layer is N-doped, and a doping concentration of the GaP ohmic contact layer is in a range of 5E18-5E19/cm³.

7. The micro light-emitting diode as claimed in claim 1, wherein the first semiconductor layer comprises a P-type window layer, a light-emitting surface is provided on a side of the P-type window layer facing away from the active layer, and a material of the P-type window layer is Alₓ₁Ga₁₋ₓ₁InP, where x1 is greater than or equal to 0 and less than or equal to 1.

8. The micro semiconductor light-emitting diode as claimed in claim 7, wherein the x1 in the Alₓ₁Ga₁₋ₓ₁InP is in a range of 0.3-0.7, a thickness of the P-type window layer is in a range of 2500-5000 nm, and a doping concentration of the P-type window layer is in a range of 2E18-5E18/cm³.

9. The micro light-emitting diode as claimed in claim 7, wherein the light-emitting surface comprises a roughened structure, and the roughened structure is composed of protrusions.

10. The micro light-emitting diode as claimed in claim 1, wherein the first semiconductor layer comprises a P-type window layer and a P-type cladding layer, and the second semiconductor layer further comprises an N-type cladding layer and an N-type ohmic contact layer;
a light-emitting surface is provided on a side of the P-type window layer facing away from the active layer, and the P-type cladding layer is located on a side of the P-type window layer facing away from the light-emitting surface and is located between the P-type window layer and the active layer; and
the N-type cladding layer is located on a side of the active layer facing away from the light-emitting surface, the N-type GaP window layer is located on the side of the active layer facing away from the light-emitting surface, the N-type cladding layer is located between the active layer and the N-type GaP window layer, the N-type ohmic contact layer is located on a side of the N-type GaP window layer facing away from the light-emitting surface, and the N-type ohmic contact layer is located between the N-type GaP window layer and the second electrode.

11. The micro light-emitting diode as claimed in claim 1, further comprising an insulation protection layer formed on a surface and a sidewall of the semiconductor epitaxial stacked layer.

12. The micro light-emitting diode as claimed in claim 11, wherein the insulation protection layer has a single-layer structure or a multi-layer structure, and is formed of at least one material selected from the group consisting of silicon dioxide (SiO₂), silicon nitride (SiNₓ), aluminum oxide (Al₂O₃), and titanium oxide (Ti₃O₅).

13. The micro light-emitting diode as claimed in claim 11, wherein the insulation protection layer is a Bragg reflective layer structure.

14. A micro light-emitting diode, comprising:
a semiconductor epitaxial stacked layer, comprising a first semiconductor layer, a second semiconductor layer, and an active layer located between the first semiconductor layer and the second semiconductor layer;
a first electrode, electrically connected to the first semiconductor layer; and
a second electrode, electrically connected to the second semiconductor layer;
wherein the second semiconductor layer comprises an N-type window layer, a material of the N-type window layer is GaP, and a thickness of the N-type window layer is in a range of 100-2000 nm.

15. The micro light-emitting diode as claimed in claim 14, wherein a doping concentration of the N-type window layer is in a range of 1E18-5E18/cm³.

16. The micro light-emitting diode as claimed in claim 14, wherein the second semiconductor layer further comprises an N-type ohmic contact layer, a material of the N-type ohmic contact layer is GaP, a light-emitting surface is provided on a side of the first semiconductor layer facing away from the active layer, the N-type window layer is located on a side of the active layer facing away from the light-emitting surface, and the N-type ohmic contact layer is located on the side of the active layer facing away from the light-emitting surface and is located between the N-type window layer and the second electrode; a thickness of the N-type ohmic contact layer is in a range of 5-100 nm; and a doping concentration of the N-type ohmic contact layer is 5E18-5E19/cm³.

17. The micro light-emitting diode as claimed in claim 14, wherein the first semiconductor layer comprises a P-type window layer, a light-emitting surface is provided on a side of the P-type window layer facing away from the active layer, a material of the P-type window layer is Alₓ₁Ga₁₋ₓ₁InP, where x1 in the Alₓ₁Ga₁₋ₓ₁InP is in a range of 0.3-0.7, a thickness of the P-type window layer is in a range of 2500-5000 nm, and a doping concentration of the P-type window layer is in a range of 2E18-5E18/cm³.

18. The micro light-emitting diode as claimed in claim 16, wherein the light-emitting surface comprises a roughened structure, and the roughened structure is composed of protrusions.

19. The micro light-emitting diode as claimed in claim 14, wherein the first semiconductor layer comprises a P-type window layer and a P-type cladding layer, and the second semiconductor layer further comprises an N-type cladding layer and an N-type ohmic contact layer;
a light-emitting surface is provided on a side of the P-type window layer facing away from the active layer, and the P-type cladding layer is located on a side of the P-type window layer facing away from the light-emitting surface and is located between the P-type window layer and the active layer; and
the N-type cladding layer is located on a side of the active layer facing away from the light-emitting surface, the N-type window layer is located on the side of the active layer facing away from the light-emitting surface, the N-type cladding layer is located between the active layer and the N-type window layer, the N-type ohmic contact layer is located on a side of the N-type window layer facing away from the light-emitting surface, and the N-type ohmic contact layer is located between the N-type window layer and the second electrode.

20. A display panel, comprising the micro light-emitting diode as claimed in claim 1.
